(19) United States
(12) Patent Application Publication
(10) Pub. No.: US 2025/0183148 A1
(43) Pub. Date: Jun. 5, 2025

(54) Electronic Device and Manufacturing Method thereof

(71) Applicant: InnoLux Corporation, Miao-Li County (TW)

(72) Inventors: Kuang-Ming FAN, Miao-Li County (TW); Po-Yun HSU, Miao-Li County (TW); Jia-Huei LIN, Miao-Li County (TW); I-Chang LIANG, Miao-Li County (TW)

(73) Assignee: InnoLux Corporation, Miao-Li County (TW)

(21) Appl. No.: 18/939,427

(22) Filed: Nov. 6, 2024

Related U.S. Application Data
(60) Provisional application No. 63/606,104, filed on Dec. 5, 2023.

(30) Foreign Application Priority Data
Jun. 27, 2024 (CN) 202410845336.1

(51) Int. Cl. H01L 23/498; H01L 21/48; H01L 21/66; H05K 1/11; H05K 3/00

(52) U.S. Cl. CPC H01L 23/49838; H01L 21/486; H01L 22/12; H01L 23/49827; H05K 1/115; H05K 3/0017; H05K 2201/09563; H05K 2203/162

(57) ABSTRACT

This disclosure provides an electronic device, which includes a core substrate, having a first surface and a second surface opposite to each other; a first through hole disposed within the core substrate and connected to the first surface and the second surface; a second through hole disposed within the core substrate and connected to the first surface and the second surface; and a conductive material filled in the first through hole and the second through hole; wherein in a sectional structure of the electronic device, a sectional profile of the first through hole is different from a sectional profile of the second through hole.

### CROSS REFERENCE TO RELATED APPLICATION

This application claims the benefit of U.S. Provisional Application No. 63/606,104, filed on Dec. 5, 2023. The content of the application is incorporated herein by reference.

### BACKGROUND OF THE DISCLOSURE

### 1. Field of the Disclosure

The present disclosure is related to an electric device and an electric device manufacturing method, and more particularly to an electric device manufacturing method using non-destructive testing steps and a manufactured electric device thereof.

### 2. Description of the Prior Art

Using through hole substrates as circuit boards is very favorable for electrical signal transmission because through hole substrates have dimensional stability, adjustable thermal expansion coefficient, low power loss at high frequency, high thermal stability, and the ability to form in thickness and large panel size. However, as the size of electronic components continues to shrink and become lighter and thinner, the critical dimensions of the through hole substrate TV process (e.g., through hole opening, through hole angle) continue to shrink, which directly affects the ease of subsequent through hole defect inspection and through hole metallization processes. In addition, the quality inspection of through hole substrates is an issue that needs to be discussed urgently.

### SUMMARY OF THE DISCLOSURE

Therefore, the purpose of the present disclosure is to provide an electric device and an electric device manufacturing method.

The present disclosure provides an electronic device manufacturing method, comprising providing a core substrate; performing a first modification step to a portion of the core substrate; performing an etching step to the portion of the core substrate to form a through hole; and performing a through hole inspection step to determine a status of the core substrate that comprises the through hole, wherein the manufacturing method further comprises performing a through-hole rework process when a determining result indicates that rework is required, and a subsequent process is carried out when the determining result indicates that the rework is not required.

The present disclosure provides an electronic device, comprising a core substrate, having a first surface and a second surface opposite to each other; a first through hole disposed within the core substrate and connected to the first surface and the second surface; a second through hole disposed within the core substrate and connected to the first surface and the second surface; and a conductive material filled in the first through hole and the second through hole; wherein in a sectional structure of the electronic device, a sectional profile of the first through hole is different from a sectional profile of the second through hole.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a cross-sectional schematic diagram of an electronic device of the present disclosure.

FIG. 2 is a schematic diagram of a manufacturing system of the electronic device of the present disclosure.

FIG. 3 is a schematic diagram of an electronic device manufacturing method of the present disclosure.

FIG. 4 is a schematic diagram of an inspection device according to a first embodiment of the present disclosure.

FIG. 5 is a schematic diagram of an inspection device according to a second embodiment of the present disclosure.

FIG. 6 is a schematic diagram of the inspection results of the present disclosure.

FIG. 7 is a schematic diagram of the inspection results of the conventional method.

FIG. 8 to FIG. 10 are schematic diagrams exposing before-and-after rework of through holes in the core substrate of the present disclosure.

FIG. 11 to FIG. 14 are schematic diagrams of electronic devices according to various embodiments of the present disclosure.

### DETAILED DESCRIPTION

The present disclosure may be understood by reference to the following detailed description of embodiments, taken in conjunction with the drawings as described below. It is noted that, for purposes of illustrative clarity and being easily understood by the readers, various drawings of this disclosure show a portion of the device or structure, and certain elements in various drawings may not be drawn to scale. In addition, the number and dimension of each element shown in drawings are only illustrative and are not intended to limit the scope of the present disclosure.

Certain terms are used throughout the description and following claims of the present disclosure for referring to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to”. When the terms “comprising”, “including” and/or “having” are used in this specification, they designate the presence of the status feature, region, step, operation and/or element, but do not exclude the presence or addition of one or more other features, regions, steps, operations, elements and/or combinations thereof.

When an element or layer is referred to as being on or connected to another element or layer, it should be understood that the element or layer is directly on or connected to another element or on another layer, or there may be other elements or layers between the two (indirectly circumstance). However, on the contrary, when the element or layer is referred to being “directly on” or “directly connected to” another element or layer, it should be understood that no intervening elements or layers are existed therebetween.

The directional terms mentioned in the embodiments, such as “up”, “down”, “left”, “right”, “front”, “back”, etc., are only directions referring to the drawings. Therefore, the directional terms used are for illustration, not for limitation of the present disclosure.

In the specification, the terms “about”, “substantially”, “around”, and “approximately” generally mean within 10% of a given value or range, or mean within 5%, 3%, 2%, 1%, or 0.5% of a given value or range. A given quantity herein is an approximate quantity, that is, even in the situation of an absence of a specific description of “about”, “substantially”, “around”, or “approximately”, it may still imply the meaning of “about”, “substantially”, “around”, or “approximately”.

The term “between value A and value B” is interpreted to include the condition of value A and value B or at least one of value A and value B, as well as other values between value A and value B.

In the present disclosure, the thickness, the length, and the width may be measured by an optical microscopy (OM), and the thickness and the length may be measured through a cross-sectional image of a scanning electron microscope (SEM), but not limited thereto. In addition, some errors or inaccuracy may exist between any two values or directions used for comparison.

In the present disclosure, the definition of roughness determination may be observed by SEM, and the peaks and valleys of the surface undulations may be seen on the concave and convex surfaces with a distance difference of 0.15 micrometers (μm) to 1 μm. Measurement of roughness judgment may include the use of SEM, transmission electron microscope (TEM), etc., to observe the surface undulation condition under the appropriate and same magnification, and by taking a single length (e.g., 10 μm) of the sample to compare the undulation condition that is the range of its roughness. Here, “appropriate magnification” means the roughness (Rz) or average roughness (Ra) of at least one surface with at least 10 undulating spikes that may be seen under the field of view of this magnification.

The ordinal terms used in the specification and claims, such as “first”, “second”, etc., are used for indicating elements in the claims. They do not imply and represent any sequential order in the claims, nor does it represent the order of a certain claimed element with respect to another claimed element, or the order of The electronic devices described herein may be used in, but are not limited to, semiconductor packaging devices, display devices, light emitting devices, backlighting devices, antenna devices, sensing devices, or splicing devices. The electronic device may be a bendable or flexible electronic device. A display device may be a non-self-luminous display device or a self-luminous display device. Antenna devices may be liquid crystal type antenna devices or non-liquid crystal type antenna devices, and sensing devices may be sensing devices for capacitance, light, heat, or ultrasonic waves, but not limited thereto. The electronic device may include an electronic component, and the electronic component may include a semiconductor component, and the semiconductor component may include, for example, a passive component and an active component, such as a capacitor, a resistor, an inductor, a diode, a transistor, an integrated circuit, and the like. The diode may include a light emitting diode, an optoelectronic diode, or a capacitive diode. The light emitting diode may, for example, include an organic light emitting diode (organic light emitting diode, OLED), a sub-millimeter light emitting diode (mini LED), a micro light emitting diode (micro LED), or a quantum dot light emitting diode (quantum dot LED), but is not limited to this. A splicing device may be, for example, a display splicing device or an antenna splicing device, but is not limited thereto. Semiconductor components may include, but are not limited to, semiconductor layers or electronic components made through a semiconductor process. It should be noted that the electronic device may be in any combination of the foregoing arrangements, but is not limited thereto. The electronic device may have a peripheral system such as a drive system, a control system, a light source system, a shelf system, etc. The electronic device may include an electronic unit. The electronic device may comprise an electronic unit, wherein the electronic unit may comprise a passive element and an active element, such as a capacitor, resistor, inductor, diode, transistor, sensor, and the like. It should be noted that the electronic devices of the present disclosure may be various combinations of the above devices, but are not limited thereto. The manufacturing method of the electronic devices disclosed herein may be applied, for example, to wafer-level package (WLP) processes or panel-level package (PLP) processes, wherein the wafer-level package or panel-level package processes may include chip-first processes or chip-last processes, but the wafer-level package or panel-level package processes may include chip-first processes or chip-last processes, but the wafer-level package or panel-level package processes may include chip-last processes. The electronic devices disclosed herein may include, for example, a chip-first process or a chip-last process, but are not limited thereto. The electronic devices of the present disclosure may be used, for example, in power modules, semiconductor packaging devices, display devices, light emitting devices, backlighting devices, antenna devices, sensing devices, or splicing devices, but are not limited thereto. Electronic devices may include, but are not limited to, System on a Chip (SoC), System in a Package (SiP), antenna in package (AiP), or various combinations of the foregoing.

It should be noted that, without departing from the spirit of the present disclosure, features in several different embodiments may be substituted, recombined, or mixed to accomplish other embodiments.

It is to be noted that the technical solutions provided in the different embodiments hereinafter may be substituted, combined or mixed with each other to constitute another embodiment without violating the spirit of the present disclosure.

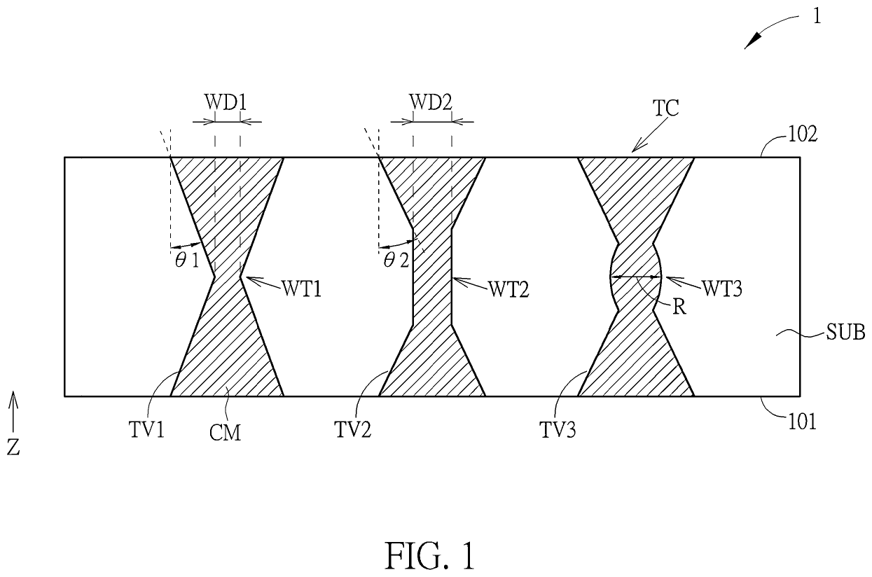

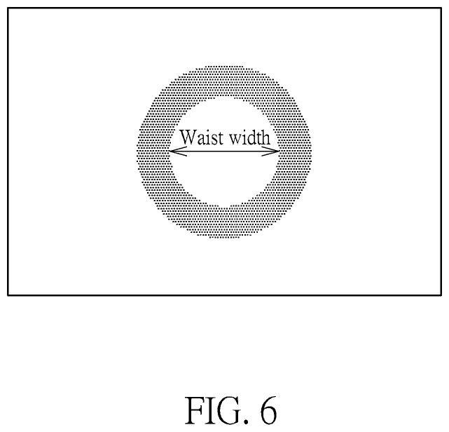

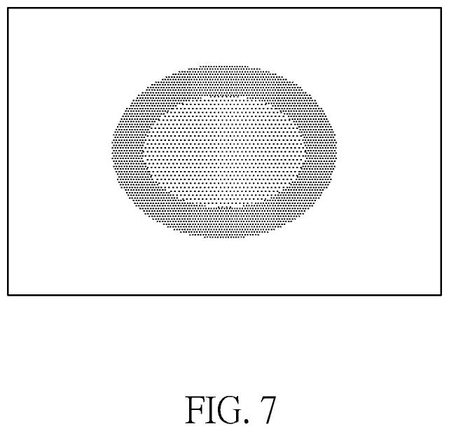

Please refer to FIG. 1. FIG. 1 is a cross-sectional schematic diagram of the electronic device 1 of the present disclosure. As shown in FIG. 1, the present disclosure provides an electronic device 1, which includes a core substrate SUB, a plurality of through holes and a conductive material CM. The core substrate SUB may be a glass, a ceramic, a wafer, an organic material, a combination of the foregoing, or other suitable material, and the glass may include, but not limited to, fused silica, an alkali glass, or an alkali-free glass. In this embodiment, the plurality of through holes are disposed within the core substrate SUB and respectively connected to a first surface 101 and a second surface 102 of the core substrate SUB. The conductive material CM may be filled in the plurality of through holes, and other electronic elements or wires may contact the conductive material CM of the electronic device 1 either directly or indirectly, through interval conductive material, to perform the transmission of electrical signals. It should be noted that the other electronic elements, the wires and the interval conductive material are well known to those skilled in the art, and are not repeated herein and are not shown in FIG. 1. In an embodiment, the plurality of through holes may include at least two of a first through hole TV1, a second through hole TV2 and a third through hole TV3. The present disclosure is not limited to FIG. 1 while illustrates the first through hole TV1, the second through hole TV2 and the third through hole TV3, and the electronic device 1 may include two or more through holes, and the types of the through holes may be more than two. In detail, according to the present disclosure, at least two of the plurality of through holes have different sectional profiles. For example, at least one of an opening width, a waist width, a sidewall inclination angle and a sidewall curved radius of the sectional profile of at least two through holes are different. Alternatively, the through holes differ in their degree of proximity to a round shape in the top-down view direction (true roundness, see FIG. 6 and FIG. 7), but the present disclosure are not limited to the foregoing. As shown in FIG. 1, for example, the sectional profile of the first through hole TV1 is different from the sectional profile of the second through hole TV2. The first through hole TV1 includes a tapered area adjacent to the first surface 101 and a tapered area adjacent to the second surface 102, and the sidewall at the intersection of the two tapered areas have a distinctly tilted turning point, which is the waist WT1 of the first through hole TV1. The waist WT1 is the only point having the minimum width WD1 in the sectional profile of the first through hole TV1, which means the width WD1 of the waist WT1 is the only minimum width in the sectional profile shape of the first through hole TV1. In comparison, the portion of the waist WT2 of the second through hole TV2 is a rectangular area having a section of equal width with both sidewalls parallel to the direction Z, wherein the direction Z is parallel to the normal direction of the first surface 101. From the above, it may be seen that the waist width WD1 (or the minimum width of the sectional profile) and shape of the first through hole TV1 is different from the waist width WD2 (or the minimum width of the sectional profile) and shape of the second through hole TV2, e.g., the width WD2 may be larger than the width WD1 but not limited to it. In another aspect, the third through hole TV3 has a waist WT3 with curved sidewalls, and thus has a different sectional profile than the first through hole TV1 and the second through hole TV2. It should be noted that in other embodiments, the plurality of through holes may include through holes with different sidewall inclination angles, through holes with curved sidewalls and non-curved sidewalls, and/or through holes with curved sidewalls having different curvature radius R, but are not limited thereto. In different embodiments, the electronic device 1 of the present disclosure may include the plurality of through holes, wherein at least two of the through holes have different sectional profiles, but some of the through holes of the plurality of through holes of the electronic device 1 may have the same sectional profiles. In the electronic device 1, a conductive material CM is provided inside the through holes of the core substrate SUB, so that the through holes and the conductive material CM inside thereof form a through hole conductive element TC, which may be used to conduct or electrically connect electronic components or wires disposed on the first surface 101 and the second surface 102. According to some embodiments, the inclination angle of the sidewall is the included angle between the extension line of the sidewall and the normal direction of the substrate, e.g., the inclination angles θ1 and 02 in FIG. 1. The electronic device 1 may be applied in any electronic component, device or product requiring the core substrate SUB and the through hole conductive element TC, such as a packaging component, a circuit board, a display panel, an illuminating device, and the like, but is not limited to the above.

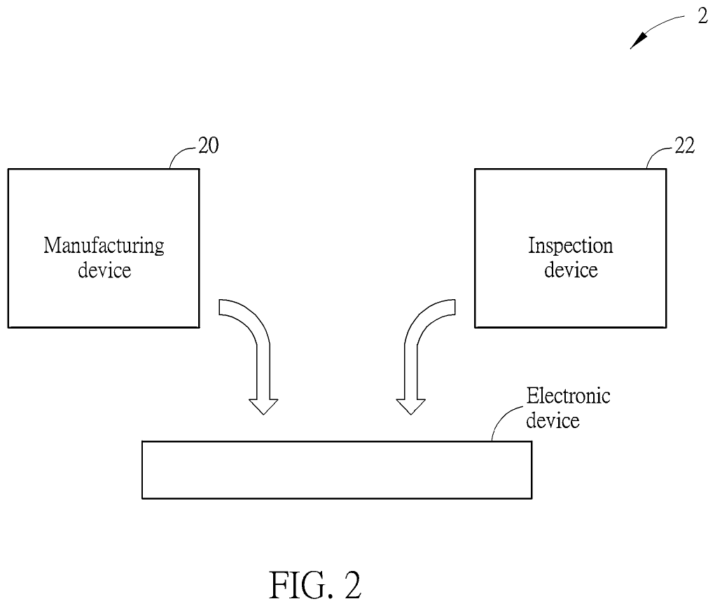

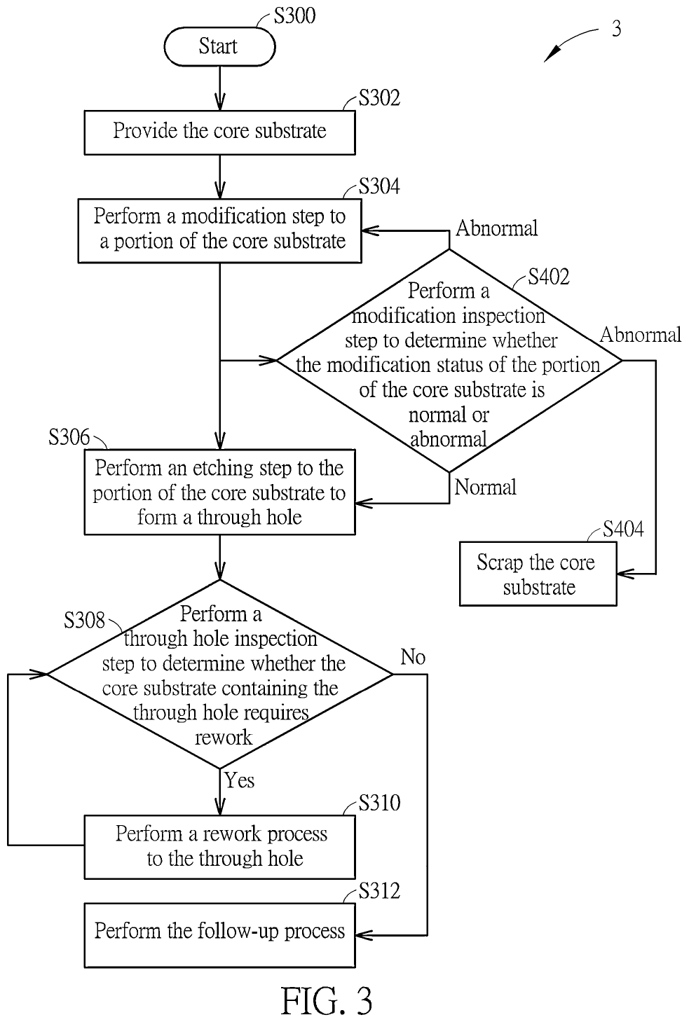

Please refer to FIG. 2, which is a schematic diagram of a manufacturing system 2 of the electronic device of the present disclosure. As shown in FIG. 2, the manufacturing system 2 includes a manufacturing device 20 and an inspection device 22, which is used to detect whether the electronic device 1 manufactured by the manufacturing device 20 includes abnormal or defective through holes or the performance of the modification process prior to making the through holes. The manufacturing device 20 may perform a rework step to the electronic device 1 according to the inspection results. It should be noted that the manufacturing device 20 and the inspection device 22 may be separate devices or integrated as one device, or the manufacturing device 20 and the inspection device 22 may integrate a controller or other computing device (e.g., an edge computing device.) to determine the inspection results, but are not limited thereto. In detail, the operation of the manufacturing system 2 may be summarized in an electronic device manufacturing method 3, as shown in FIG. 3. The electronic device manufacturing method 3 includes the following steps:

Step S300: Start.

Step S302: Provide the core substrate.

Step S304: Perform a modification step to a portion of the core substrate.

Step S306: Perform an etching step to the portion of the core substrate to form a through hole.

Step S308: Perform a through hole inspection step to determine whether the core substrate containing the through hole requires rework; when the core substrate requires rework, perform step S310; when the core substrate does not require rework, perform step S312.

Step S310: Perform a rework process to the through hole.

Step S312: Perform the follow-up process.

According to the electronic device manufacturing method 3, the post-modified status of the core substrate may also optionally be confirmed before step S306, including the following steps:

Step S402: Perform a modification inspection step to determine whether the modification status of the portion of the core substrate is normal or abnormal; when the modification status is normal, proceed to step S306; when the modification status is abnormal, confirm whether the modification may be done again or it is not possible to remedy the problem; if it is possible to re-modify the portion to improve the modification status, proceed to step S304; if it is confirmed that the modification is not possible to remedy the problem, then proceed to step S404.

Step S404: Scrap the core substrate.

According to step S304 of the electronic device manufacturing method 3, the manufacturing device 20 may perform a modification step to a portion of the core substrate. In detail, laser light may be used to irradiate portions of the core substrate so that modification occurs by changing the crystalline composition of those portions. For example, the bonding capacity of the areas of the substrate or the core substrate that have been modified by the laser light is different from that of the areas that have not been modified by the laser light, i.e., the structure of the areas that have been modified by the laser light is weakened. As another example, the refractive index of light of the areas that have been modified by the laser light is different from the refractive index of light of the areas that have not been modified by the laser light, but not limited thereto. According to the inspection results, it is judged whether the performance of laser modification meets the setting, and if it does not, the modification step may be carried out again.

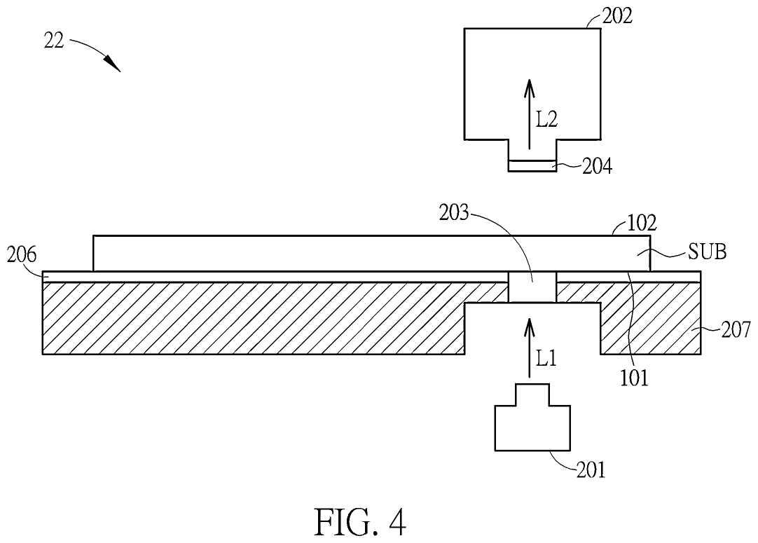

In step S402, the inspection device 22 may perform a modification inspection step to the electronic device for determining whether the modification status of the modified portion of the core substrate is normal or abnormal. In detail, please refer to FIG. 4. FIG. 4 is a schematic diagram of the inspection device 22 according to an embodiment of the present disclosure. The inspection device 22 includes a first inspection light generator 201, an inspection light receiver 202, and a first optical film assembly 203, and optionally includes a carrier table 207. The first inspection light generator 201 may provide a first light L1, and enable the first light L1 to pass through the first optical film assembly 203 and then pass through an inspection area containing the modified portion of the core substrate SUB. It should be noted that the first optical film assembly 203 may be disposed in a projection area adjacent to the first surface 101 corresponding to the inspection area, but not limited thereto. The first optical film assembly 203 may include a polarizer. In other words, the first optical film assembly 203 may be considered as a polarization generator. When the first light L1 passes through the first optical film assembly 203, the first optical film assembly 203 generates a collimated light, which means the first light L1 includes a collimated light after it passes through the first optical film assembly 203. After the collimated light passes through the core substrate SUB, the inspection light receiver 202 may receive the collimated light and generate an inspection result. The inspection light receiver 202 may include a second optical film assembly 204 that may be disposed of a side of the inspection light receiver 202 adjacent to the second surface 102, but not limited thereto. The second optical film assembly 204 may include another polarizer whose polarization direction is different from that of the polarizer of the first optical film assembly 203, such as the polarization directions of which are orthogonal to each other. Under the above design, the second optical film assembly 204 may be regarded as including an analyzer that may be used to inspect the polarization status of the received light. During the inspection process, the first light L1 containing collimated light passes through the inspection area. The modified area and unmodified area of the core substrate SUB have different refractive characteristics. For example, the modified area will cause the first light L1 to have a larger refractive angle. Before the first light L1 enters the inspection light receiver 202, it will pass through the first optical film assembly 203 to form the second light L2, and then the inspection result may be obtained by the camera system in the inspection light receiver 202 after the second light L2 travels to the camera system, in which the modified portion will form a bright spot or a white spot, and the unmodified area will be a dark area. In this embodiment, the carrier table 207 may be a black anodized platform, but not limited to the above. The carrier table 207 may also have other colors or not be anodized. Through the above design, it may make the obtained image of inspection more obvious, so as to improve the defect detection rate, but the present disclosure is not limited to this.

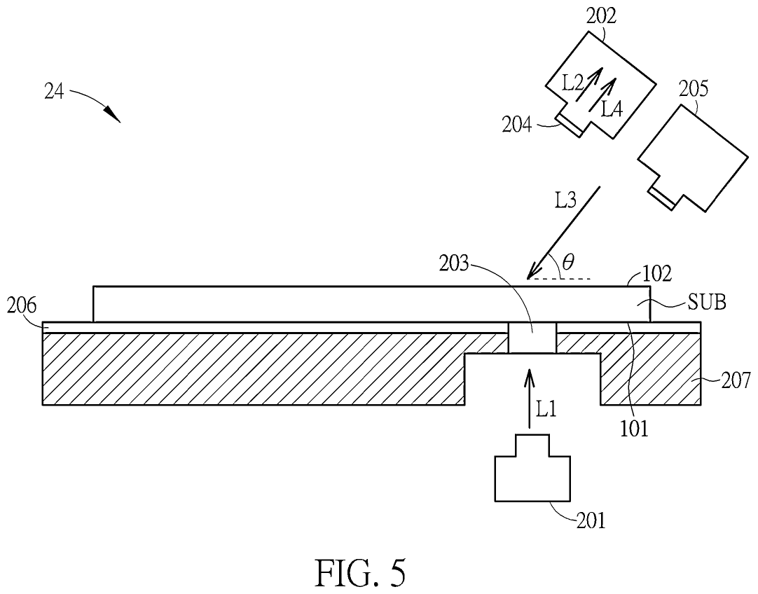

In another aspect, the inspection device of the presently disclosed electronic device may utilize not only a backlight source (corresponding to the first surface 101) such as the first inspection light generator 201 for inspecting the electronic device, but also a front light source (corresponding to the second surface 102) to inspect the electronic device for performing step 308 to carry out the through hole inspection step. Please refer to FIG. 5. FIG. 5 is a schematic diagram of the inspection device 24 of the present disclosure. The inspection device 24 may be derived from the inspection device 22, so the same components are indicated by the same symbols. The difference between the inspection device 24 and the inspection device 22 is that the inspection device 24 further includes a second inspection light generator 205 and a third optical film (layer) assembly 206. The second inspection light generator 205 is disposed on the side of the second surface 102 of the core substrate SUB as a front light source, which may provide a third light L3 to enable the third light L3 to pass through the inspection area of a portion of the core substrate SUB and then to travel to the third optical film assembly 206 to generate the fourth light L4. The inspection light receiver 202 may receive the fourth light L4 to inspect the through hole status of the core substrate SUB and generate an inspection result to indicate whether the core substrate containing the through hole needs to be reworked. It should be noted that the third optical film assembly 206 may be or include a reflective film, which may include, for example, but not be limited to, a metallic material or a highly reflective material. In addition, the second inspection light generator 205 may be moved or rotated in different directions (including X-Y, Y-Z, X-Z, or X-Y-Z) to control the incidence angle θ of the third light L3 in a range from 10 degrees to 170 degrees, but not limited thereto. According to some embodiments, the third light L3 may be a ring-shaped front light source or a backlight source, but not limited thereto. The inspection light receiver 202 may also be located at a relative position or angle to facilitate reception of the fourth light L4 to obtain better inspection results. In this way, when the through hole of the core substrate SUB is abnormal or defective, the manufacturing device 20 may re-execute a rework step (e.g., including a modification step, an etching process, and/or a laser process) to the through hole of the core substrate SUB until the through hole of the core substrate SUB is normal or free of defects. It should be noted that the third optical film assembly 206 may be a film layer that is directly coated or formed on the surface of the carrier table 207, or it may be a layer of film element that may be separated from the carrier table 207.

In another embodiment, during the through hole inspection step of step S308, a backlight may also be used for inspection. For example, the first inspection light generator 201 may be used to generate the first light L1, which passes through the first optical film assembly 203 so as to contain collimated light and then travels to the core substrate SUB to pass through the area to be inspected, with cooperation of the third optical film assembly 206 that reflects the light to form the fourth light L4, which is then processed by the inspection light receiver 202 to determine the through hole status of the core substrate SUB as acceptable, requiring rework, or to be scrapped, etc., by utilizing the fact that the areas with through holes and without through holes have different refractive and scattering characteristics, but the present disclosure is not limited to this. For example, if the core substrate SUB after the through hole forming step is determined to be in need of reworking, the through hole reworking process will be carried out, and if the result of the determination is that it is not in need of reworking, the subsequent process will be carried out.

It should be noted that the inspection device 22 and the inspection device 24 are only embodiments of the present disclosure, and those skilled in the art may make appreciative adjustments according to the system requirement. For example, the inspection light receiver 202 may be a photographic element, such as, but not limited to, a 2D optical microscope (2D-OM). The second detecting light generator 205 may be a ring-shaped front light source that generates a third light L3 in a ring-shaped distribution incident on a portion of the core substrate SUB. In addition, the first light L1 and the third light L3 may include visible light with a wavelength greater than 400 (full-color light) nm and/or invisible light with a wavelength range from 700 nm to 1700 nm (near-infrared or short-wave infrared), but not limited thereto. The laser process includes, but is not limited to, using laser light with a wavelength of 1064 nm, 532 nm, or 266 nm to perform the rework step.

Please refer to FIG. 6 and FIG. 7. FIG. 6 is a schematic diagram of the inspection results of the present disclosure and FIG. 7 is a schematic diagram of the inspection results of the conventional method. As shown in FIG. 6, due to the disposition of the third optical film assembly 206, the inspection results of the present disclosure inspection device for inspecting the electronic device have high contrast and high resolution, and the maximum size and the minimum size (i.e., the portion having a waist width) of the through hole may be clearly seen. Compared to FIG. 7, the waist width of the through hole of the core substrate SUB in FIG. 6 is clearly visible. Those skilled in the art may determine whether the through hole of the core substrate SUB needs to be reworked according to the waist width of the through hole. On the contrast, the inspection result according to the conventional method shown in FIG. 7 is unclear that the minimum size of the through hole cannot be distinguished from the whole image easily.

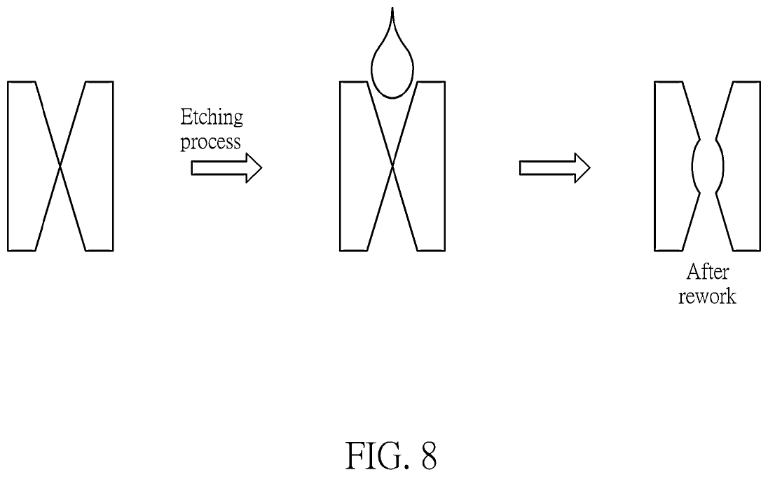

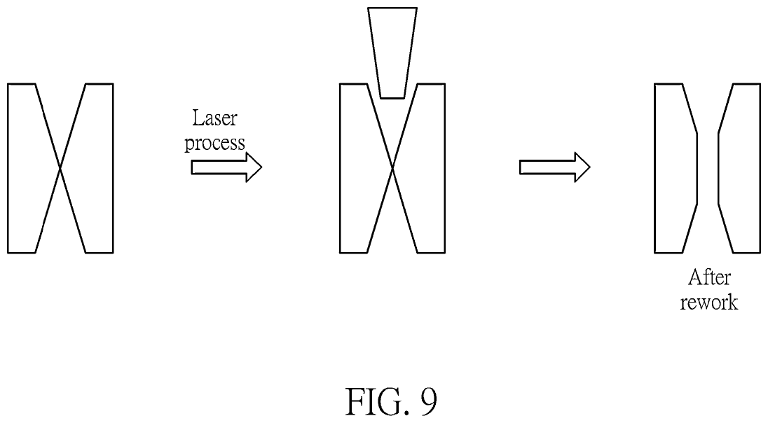

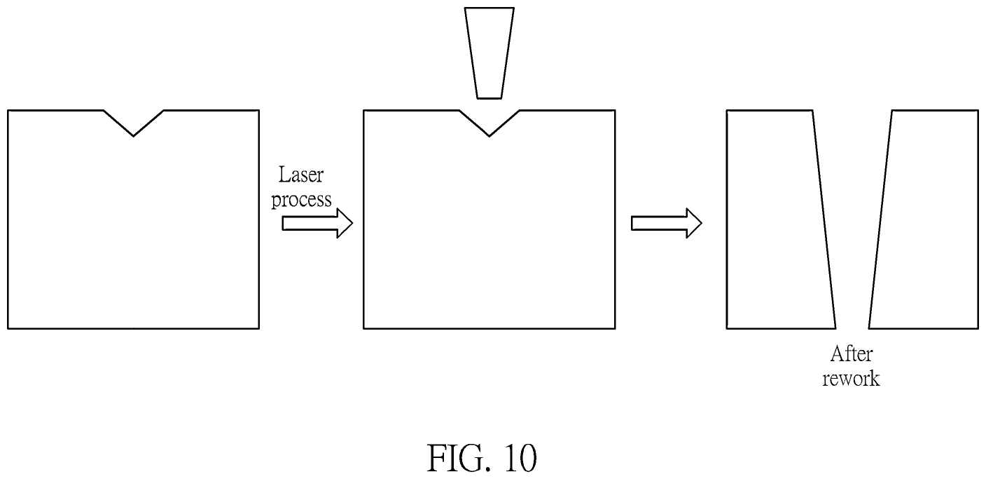

Please refer to FIG. 8 to FIG. 10. FIG. 8 to FIG. 10 are schematic diagrams of the through holes in the core substrate SUB before and after rework of the present disclosure. The manufacturing device 20 may perform a rework step for a through hole having defects (the through hole does not connect the first surface and the second surface of the core substrate SUB or does not penetrate the core substrate SUB). For example, as shown in FIG. 8, the rework step may be performed by an etching process, which may include dry etching or wet etching. Taking wet etching as an example, when the modified area is re-etched with an etching solution, a through hole penetrating through the first surface and the second surface of the core substrate SUB may be formed after the etching process is completed. For instance the sidewall of the through hole's waist may exhibit curved features, straight line features, or width with gradational change from one side of the core substrate, but not limited thereto. In addition, as shown in FIGS. 9 and 10, the rework step may be performed by using a laser process, whereby the waist of the through hole after the laser process will exhibit rectangular features or tapered features. Accordingly, electronic devices manufactured and/or reworked by the presently disclosed manufacturing device and inspection device may have a plurality of through holes with different sectional profiles from each other.

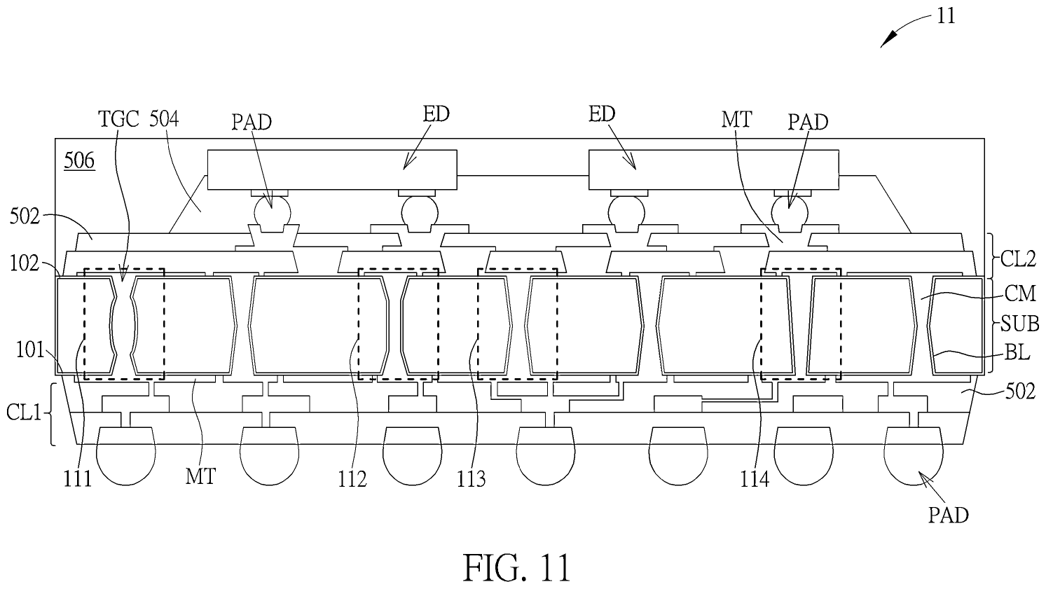

Please refer to FIG. 11 to FIG. 14. FIG. 11 to FIG. 14 are schematic diagrams of electronic devices according to various embodiments of the present disclosure. As shown in FIG. 11, the electronic device 11 includes a core substrate SUB with a plurality of through holes (111, 112, 113, 114) formed in the core substrate SUB, which through holes may have at least two kinds of sectional profiles, so as to each have a different characteristic. For example, the through hole 114 has a different opening width from the other through holes, the through hole 112 has a different waist width and a different inclination angle of the sidewall from the other through holes, or through hole 111 has a different curvature radius of sidewall from the other through holes, but not limited thereto. That is, four through holes having four different sectional profile characteristics are included in the electronic device 11. Each of the through holes and the conductive material CM disposed therein may separately form a through hole conductive element TC. In some embodiments, the through hole conductive element TC may be fabricated by forming a buffer layer BL inside the through holes and then forming the conductive material CM inside the through holes. In another aspect, the first surface 101 and the second surface 102 of the electronic device 11 may be selectively provided with a circuit layer CL1 and a circuit layer CL2, respectively, and contact pads PADs may be provided on the surfaces of the circuit layer CL1 and the circuit layer CL2 and electrically connected to each of the through hole conductive elements TCs through the conductive layer MT, respectively. The circuit layer CL1 and the circuit layer CL2 may each be a redistribution line (RDL) layer including one or more layers of insulating layers 502, and the conductive layer MT may be disposed on the surfaces of the insulating layers 502 and in the through holes in the insulating layers 502. The electronic device 11 may further include one or more electronic elements ED, such as, but not limited to, an integrated circuit chip, a capacitive chip, and the like, whose connection pads may transmit a telecommunication signal through the path formed by the contact pad PAD, the conductive layer MT, and the respective through hole conductive element TC. In addition, the electronic device 11 may also include a bottom filler layer 504 disposed on the lower side of the electronic elements ED and encompassing the contact pads PAD on the lower side thereof. The electronic device 11 may also include a packaging layer 506 covering and encompassing the electronic elements ED as well as the bottom filler layer 504. As described above, the electronic device 11 shown in FIG. 11 compose an electronic device packaging element.

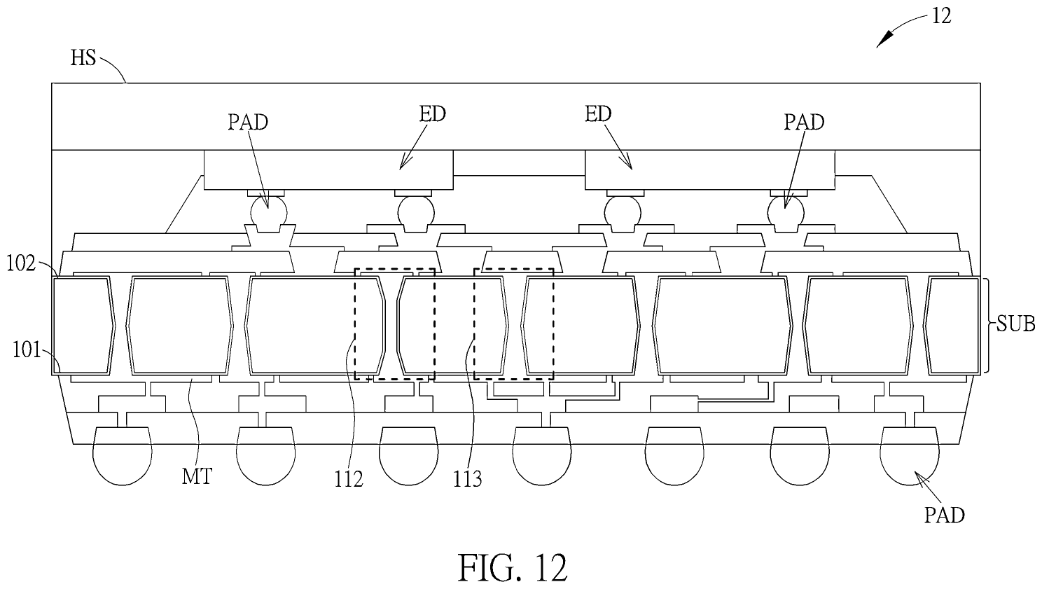

The structures and methods of fabrication of the other layers of the electronic devices 11-14 are well known in the art, and those skilled in the art may combine, modify, or vary the above-described embodiments in accordance with the spirit of the present disclosure, without limitation. For example, as shown in FIG. 12, the electronic device 12 may further include a heat dissipation structure HS, which is disposed on the electronic element ED. In this way, enhancing the heat dissipation effect of the electronic device 12 is advantageous. The electronic device 12 may optionally include a heat-conducting material, which may be disposed between the heat dissipation structure HS and the electronic elements ED, thereby further enhancing the heat dissipation effect of the electronic device 12. In addition, the heat-conducting material may optionally fill the gap between the heat-dissipation structure HS and the electronic elements ED, thereby facilitating the transfer of heat generated by the electronic elements ED through the heat-conducting material to the heat-dissipation structure HS, and from the heat-dissipation structure HS to the exterior of the electronic device 12. The material of the heat dissipation structure HS may include metal, silicon, silicon carbide, graphite, graphene, other suitable materials, or a combination of the foregoing materials, but is not limited thereto. The heat conducting material may include metal, graphite, graphene, other suitable materials, or a combination of the foregoing materials, but is not limited thereto.

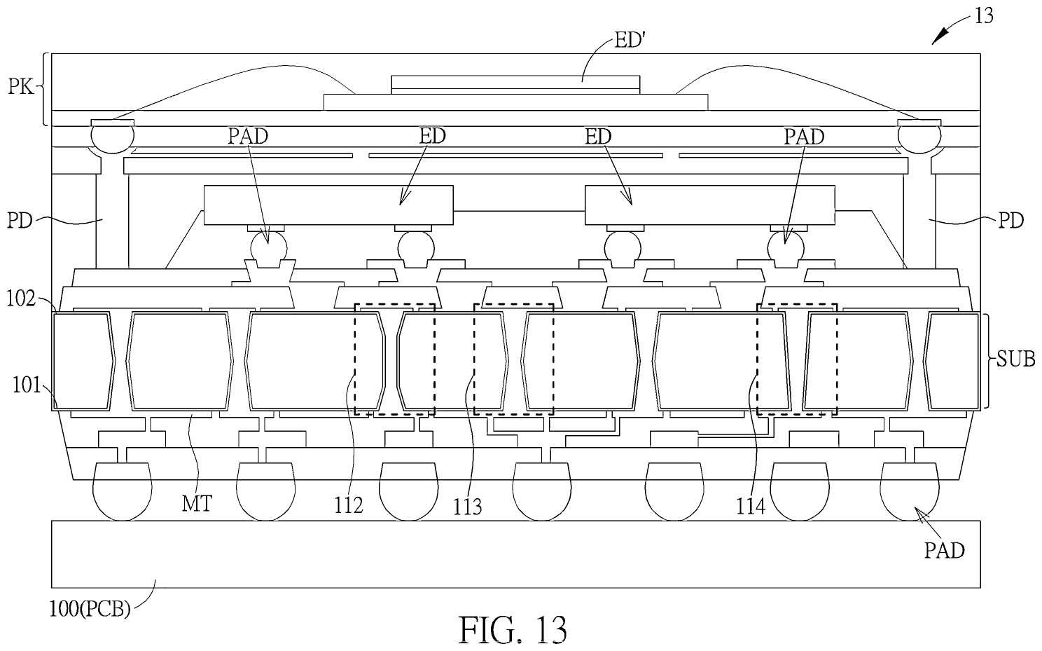

In some embodiments, the electronic device 13 may be disposed on a substrate 100, as shown in FIG. 13. The substrate 100 may be, for example, a printed circuit board (PCB), a package substrate, a substrate like PCB (SLP), but not limited thereto, as long as the substrate can provide an electrical connection function. For example, a substrate that may provide an electrical connection function by including insulating layer (s) and wire structure (s) disposed therein may be suitable for use as the substrate 100 of the present disclosure. In an embodiment of the present disclosure, the substrate 100 includes a substrate, redistributed layer structures formed on the upper and lower surfaces of the substrate, and through holes penetrating through the substrate, and the substrate may comprise glass or silicon. The electronic elements ED and/or the core substrate SUB may be electrically connected to the substrate 100 through the contact pads PAD. In another aspect, the substrate 100 may also be considered as part of the electronic device 13 of the present disclosure, i.e., the electronic device 13 also includes, for example, but not limited to, a substrate 100 representing a printed circuit board. Furthermore, the electronic device 13 may also include at least one support element PD in the package PK. The package PK is disposed on the electronic elements ED and may include another electronic element ED′, for example, but not limited to, a light emitting element or other suitable electronic element. The support element PD is disposed between the core substrate SUB and the package PK, and the upper end and the lower end of the support element PD connect and contact the redistribution layer (or circuit layer) on the lower side of the package PK and the redistribution layer (or circuit layer) on the upper surface of the core substrate SUB, respectively, so that it is advantageous to maintain the spacing between the package PK and the core substrate SUB and to prevent components, such as electronic elements ED, which are disposed between the package PK and the core substrate SUB from being damaged by pressure. In the embodiment, the number of support elements PD is exemplified as a plurality of support elements PD, and the support elements PD are spaced apart from each other, e.g., the plurality of support elements PD may be equally spaced apart from each other, but not limited thereto. In addition, one or some of the support elements PDs may be disposed in a peripheral area of the electronic device 13, such as at the outer side of one electronic element ED, and one or some of the support elements PDs (not shown in FIG. 13) may be disposed in a central area of the electronic device 13, such as at the inner side of one electronic element ED or between two of the electronic elements ED, whereby the support effect provided by the support elements PD may be further enhanced. The support elements PD may have a pillar structure respectively or may form an unclosed circular structure together, but not limited thereto. The material of the support elements PD may include, but is not limited to, metal, silicon, silicon carbide, quartz, glass, other suitable materials, or a combination of the foregoing. In some embodiments, the electronic element ED′ in the package PK may be electrically connected to the core substrate SUB through the support element(s) PD, and may be further electrically connected to the substrate 100 through the core substrate SUB.

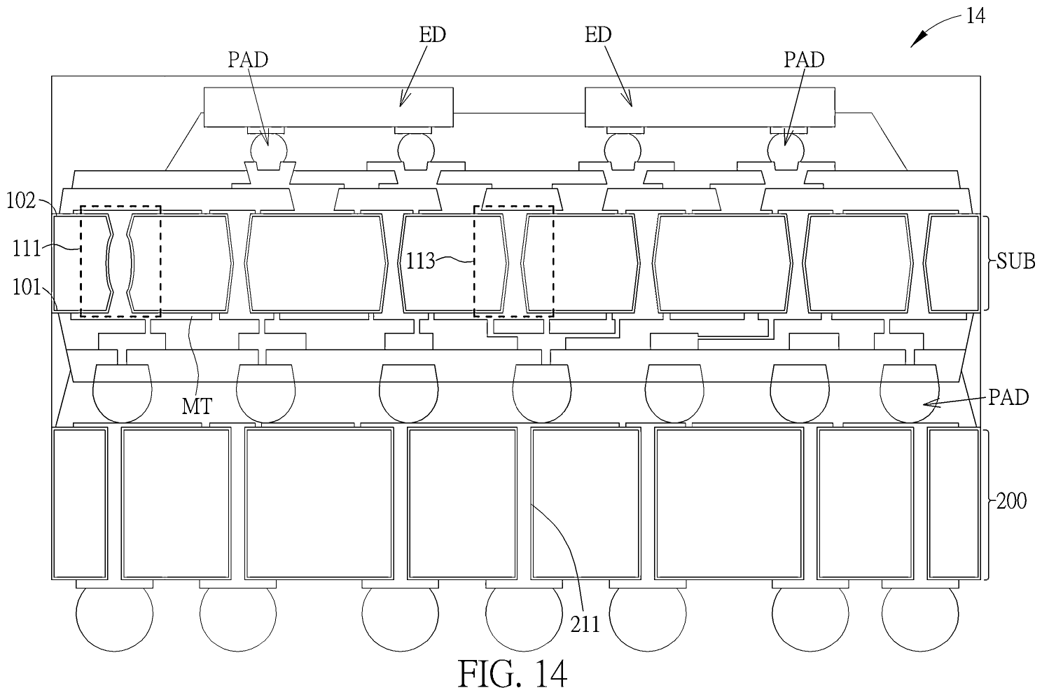

In some embodiments, as shown in FIG. 14, the electronic device 14 may also include an intermediary layer 200 (or another core substrate). The intermediary layer 200 may be disposed underneath the core substrate SUB or between the core substrate SUB and the substrate 100 (not shown in the figure). The electronic elements ED may be electrically connected to the substrate 100 through the through holes in the core substrate SUB and the intermediary layer 200, which is advantageous to enhance the maximum utilization of the plane space, and allow for a denser configuration of the electronic elements ED in the electronic device 14, which may satisfy today's trend towards miniaturization of electronic products. In some embodiments, when the intermediary layer 200 is another core substrate, the sectional profiles of the plurality of through holes 211 therein may all have similar shapes, or the plurality of through holes 211 may be similar to the through holes in the core substrate SUB, having not identical sectional profiles or sidewall shapes.

In summary, the electronic device manufacturing method of the present disclosure performs a modification step to a portion of the core substrate, and then determines whether the through holes of the modified core substrate need to be reworked. Compared to conventional methods, the present disclosure may provide inspection results with good contrast or resolution. In this way, the rework process of electronic devices may be performed more efficiently, thereby reducing costs.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a core substrate, having a first surface and a second surface opposite to each other;
a first through hole disposed within the core substrate and connected to the first surface and the second surface;
a second through hole disposed within the core substrate and connected to the first surface and the second surface; and
a conductive material filled in the first through hole and the second through hole;
wherein in a sectional structure of the electronic device, a sectional profile of the first through hole is different from a sectional profile of the second through hole.

2. The electronic device of claim 1, wherein a minimum width of the sectional profile of the first through hole is different from a minimum width of the sectional profile of the second through hole.

3. The electronic device of claim 1, wherein an inclination angle of a sidewall of the first through hole is different from an inclination angle of a sidewall of the second through hole.

4. The electronic device of claim 1, wherein at least one of the first through hole and the second through hole comprises a curved sidewall.

5. The electronic device of claim 4, wherein a curvature radius of the sidewall of the first through hole is different from a curvature radius of the sidewall of the second through hole.

6. An electronic device manufacturing method, comprising:
providing a core substrate;
performing a first modification step to a portion of the core substrate;
performing an etching step to the portion of the core substrate to form a through hole; and
performing a through hole inspection step to determine a status of the core substrate that comprises the through hole,
wherein the manufacturing method further comprises performing a through-hole rework process when a determining result indicates that rework is required, and a subsequent process is carried out when the determining result indicates that the rework is not required.

7. The electronic device manufacturing method of claim 6, wherein the through hole inspection step comprises:
providing a first light, allowing the first light to pass through a first optical film assembly, and then pass through the portion of the core substrate; and
allowing the first light to pass through a second optical film assembly to generate a second light, and utilizing the second light to determine whether a modification status of the portion of the core substrate is normal or abnormal.

8. The electronic device manufacturing method of claim 7, wherein the first light comprises a collimated light after passing through the first optical film assembly.

9. The electronic device manufacturing method of claim 8, wherein the first optical film assembly comprises a polarizer, and the polarizer enables the first light to generate the collimated light.

10. The electronic device manufacturing method of claim 9, wherein the second optical film assembly comprises an analyzer.

11. The electronic device manufacturing method of claim 10, wherein a polarization direction of the polarizer is different from a polarization direction of the analyzer.

12. The electronic device manufacturing method of claim 7, wherein the through hole inspection step further comprises:
providing a third optical film assembly;
disposing the core substrate on the third optical film assembly;
providing a third light, allowing the third light to pass through the core substrate and travel to the third optical film assembly to generate a fourth light;
determining whether a status of the through hole is normal or abnormal according to the fourth light or the second light; and
performing a rework step to the through hole when determining the through hole is abnormal;
wherein the rework step comprises a laser process or an etching process.

13. The electronic device manufacturing method of claim 12, wherein the third optical film assembly comprises a reflective film.

14. The electronic device manufacturing method of claim 13, wherein the reflective film comprises a metallic material.

15. The electronic device manufacturing method of claim 12, wherein the third light comprises a visible light having a wavelength greater than 400 nanometers or an invisible light having a wavelength within a range from 700 nanometers to 1700 nanometers.

16. The electronic device manufacturing method of claim 12, wherein the through hole inspection step comprises utilizing a inspection light receiver to receive the fourth light to inspect the status of the through hole of the core substrate.

17. The electronic device manufacturing method of claim 12, wherein the third light is a ring-shaped light source or a backlight source.

18. The electronic device manufacturing method of claim 16, wherein an included angle of the third light and a surface of the core substrate ranges from 10 degrees to 170 degrees.

19. The electronic device manufacturing method of claim 16, wherein the inspection light receiver comprises a photographic element.

20. The electronic device manufacturing method of claim 12, wherein the laser process comprises using laser light with a wavelength of 1064 nanometers, 532 nanometers or 266 nanometers to perform the rework step.
